(19) United States
(12) Patent Application Publication
(10) Pub. No.: US 2026/0314449 A1
(43) Pub. Date: Oct. 8, 2026

(54) INTEGRATED CIRCUIT DEVICE AND METHOD OF FABRICATION

(71) Applicant: TAIWAN SEMICONDUCTOR MANUFACTURING COMPANY, LTD., Hsinchu (TW)

(72) Inventor: Kuan-Ting CHOU, Hsinchu (TW)

(21) Appl. No.: 19/265,884

(22) Filed: Jul. 10, 2025

Related U.S. Application Data
(60) Provisional application No. 63/783,054, filed on Apr. 3, 2025.

(51) Int. Cl. H01L 23/538; H01L 21/48; H01L 23/00; H01L 25/18; H10B 80/00; H10D 80/30

(52) U.S. Cl. CPC H10W 70/65; H10W 70/05; H10W 70/095; H10W 70/611; H10W 70/685; H10B 80/00; H10D 80/30; H10W 90/00; H10W 90/724

(57) ABSTRACT

An integrated circuit device includes: a die; an interconnect at least partially overlapping the die; and a plurality of bumps where the interconnect and die overlap. The interconnect includes at least a first conductive layer and a second conductive layer, the plurality of bumps includes a first bump and a second bump, each of the first and second conductive layers includes a plurality of signal conductors between the first and second bumps and a plurality of ground conductors between the first and second bumps, and all of the signal conductors in each of the first and second conductive layers between the first bump and the second bump are between corresponding pairs of ground conductors in the corresponding conductive layer, and the pairs of ground conductors are continuously coupled within the first and second conductive layers from a first side to a second side of the plurality of signal conductors.

### PRIORITY CLAIM AND CROSS-REFERENCE

This application claims the benefit of U.S. Provisional Application No. 63/783,054, filed Apr. 3, 2025, which is herein incorporated by reference in its entirety.

### BACKGROUND

Integrated circuit devices have become increasingly complex with advances in technology. Although device designs that perform a variety of different functions on a same die can be advantageous, yield challenges can offset such advantages as the die becomes increasingly large and more complex. Further, advances in process nodes can make dividing functions among two or more differently-fabricated dies, each optimized for its own process node, advantageous. Some integrated circuit devices therefore include two or more dies that are coupled together in a same package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-section of an integrated circuit device according to some embodiments.

FIG. 2A is a schematic cross-section of an interconnect according to some embodiments.

FIG. 2B is a plan view of an interconnect according to some embodiments.

FIG. 2C is a schematic cross-section of an integrated circuit (IC) device according to some embodiments.

FIG. 3 is a detailed view of a region of continuous ground wiring structure in FIG. 2A according to some embodiments.

FIG. 4 is a schematic cross-section of an interconnect according to some embodiments.

FIG. 5 is a schematic cross-section of an interconnect according to some embodiments.

FIG. 6 is a schematic cross-section of an interconnect according to some embodiments.

FIG. 7 is a schematic cross-section of an interconnect according to some embodiments.

FIG. 8A is a plan view of an interconnect according to some embodiments, and FIG. 8B is a schematic cross-sectional view of the interconnect of FIG. 8A.

FIG. 9 is a schematic cross-section of an interconnect according to some embodiments.

FIG. 10 is a schematic cross-section of an interconnect according to some embodiments.

FIG. 11A is a flowchart of a method of manufacturing an integrated circuit device according to some embodiments.

FIG. 11B is a flowchart of a method of manufacturing an integrated circuit device according to some embodiments.

FIG. 12 is a block diagram of an electronic design automation (EDA) system in accordance with some embodiments.

FIG. 13 is a block diagram of an integrated circuit (IC) manufacturing system, and an IC manufacturing flow associated therewith according to some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to some embodiments, an integrated circuit device includes a die that is physically and electrically coupled to an interconnect as next-level substrate by a plurality of conductive bumps. A conductive path in the interconnect that carries signals to and/or from the die, e.g., to and/or from the die to another die, can have an impact on the integrity of the signals.

As device integration increases and/or device structures are made increasingly small and dense, a large number of signals may be carried through closely-spaced conductive structures. Increasing the numbers and/or sizes of conductors (wiring) for signals can help to maintain signal integrity, but such increases may involve reducing the numbers and/or sizes of ground conductors, which can degrade signal integrity.

According to some embodiments, signal, power, and ground wiring in an interconnect is designed to enhance signal conductor width while providing a ground wiring structure that helps maintain signal integrity. Multiple conductive layers in an interconnect are used to route signals, power, and ground within the interconnect, e.g., in wiring between a first die and a second die that are mounted adjacent to each other on a surface of the interconnect. The interconnect includes a continuous ground wiring structure formed in multiple conductive layers adjacent to the mounting surface to enhance signal integrity. The width of signal lines in the interconnect is increased relative to another approach that does not use a continuous ground wiring structure.

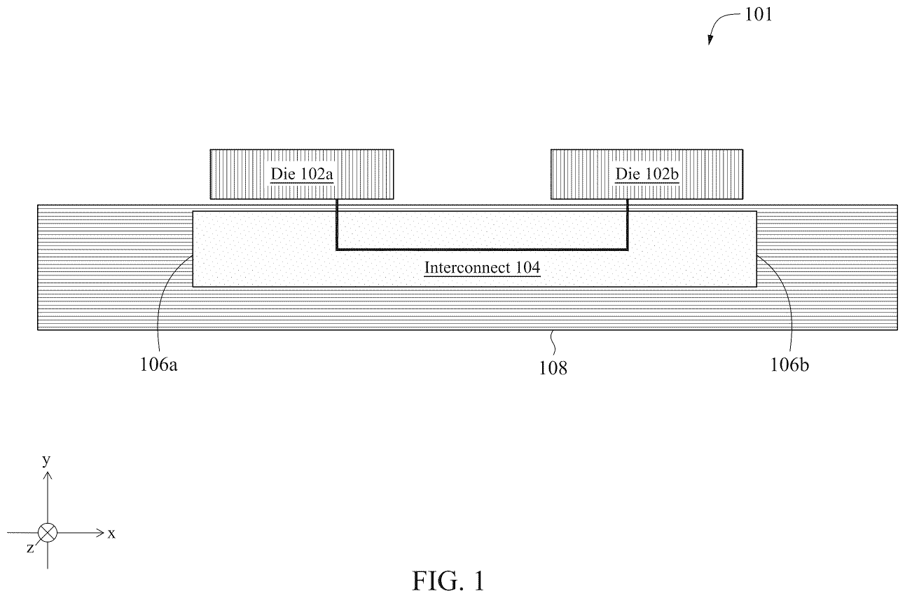

FIG. 1 is a schematic cross-section along an X-Y plane of an integrated circuit (IC) device 101 according to some embodiments.

The integrated circuit device 101 includes a first die 102a and a second die 102b (the first and second dies 102a and 102b may be referred to individually or collectively as dies(s) 102). The first and second dies 102a and 102b are spaced apart in a first direction parallel to the X axis. In some embodiments, the first and second dies 102a and 102b are each integrated circuit dies, e.g., semiconductor dies, having a plurality of active and/or passive circuits formed therein.

The first and second dies 102a and 102b are interconnected through an interconnect 104. The first and second dies 102a and 102b and the interconnect 104 are in a same package.

The first and second dies 102a and 102b are bonded to a surface of the interconnect 104 in at least a part of a region where the respective die overlaps the interconnect 104. The interconnect 104 transmits reference voltages (e.g., at least one power voltage and a ground voltage) to/from and/or between the first and second dies 102a and 102b. The interconnect 104 also transmits signals to/from and/or between the first and second dies 102a and 102b. In some embodiments, the reference voltages are substantially constant during operation of the device (e.g., an always-on power supply, ground, or the like), as compared to signals that vary with operation of the device (e.g., vary during operation of a circuit to turn gates on and off, such as when processing, transmitting, or receiving data, or the like).

In FIG. 1, the interconnect 104 is mounted to or embedded in a next-level substrate 108 such as an organic substrate that includes FR4 or the like. In some embodiments, the next-level substrate 108 includes a plurality of conductive layers therein, e.g., a plurality of metal layers coupled together by a plurality of vias. In other embodiments, a next-level substrate is not used.

In some embodiments, the first die 102a is a memory die such as a high bandwidth memory (e.g., HBM2, HBM3, or the like), and the second die 102b is a logic die such as a processor (e.g., a central processing unit (CPU), a graphics processing unit (GPU), a neural processing unit (NPU), or the like), an ASIC, or the like. In some embodiments, the first die 102a is one of a processor and a coprocessor and the second die 102b is the other of the processor and the coprocessor. The first and/or second dies 102a and 102b are bare dies in some embodiments and are packaged as chips in other embodiments.

In some embodiments, the interconnect 104 is a local silicon interconnect (LSI) embedded in an organic substrate or the like, a silicon interposer (e.g., having through-silicon vias and controlled collapse chip connection bumps on an opposite side), or the like. In some embodiments, the interconnect 104 is, or is part of, a mother board, an organic substrate including FR4 or the like, a printed circuit board, a printed wiring board, a redistribution layer, or the like.

In some embodiments, the integrated circuit device 101 is implemented as, or as part of, a package such as an integrated fan-out package, an integrated fan-out package having a package-on-package structure, a chip-on-wafer-on-substrate package, a flip-chip package, an embedded multi-die interconnect bridge, a 2.5D or 3D package, or the like.

In FIG. 1, each of the first and second dies 102a and 102b is fully vertically overlapped by the interconnect 104, where vertical refers to a second direction parallel to the Y axis. That is, the first die 102a does not extend beyond a first side 106a of the interconnect 104, and the second die 102b does not extend beyond a second side 106b of the interconnect 104. In other embodiments, one or both of the first and second dies 102a and 102b is partially overlapped by the interconnect 104 (not shown in FIG. 1) such that the first die 102a extends beyond the first side 106a of the interconnect 104 and/or the second die 102b extends beyond the second side 106b of the interconnect 104.

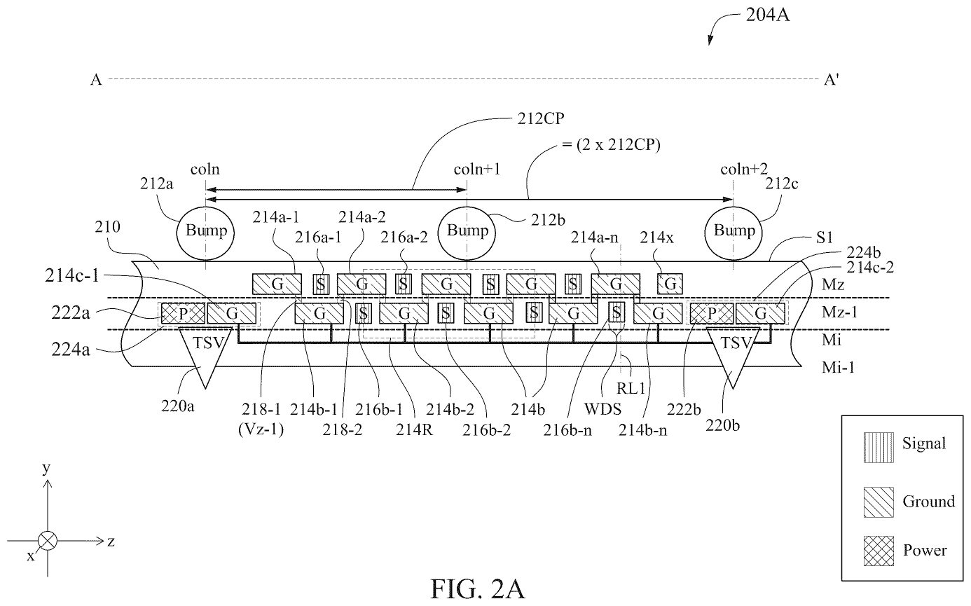

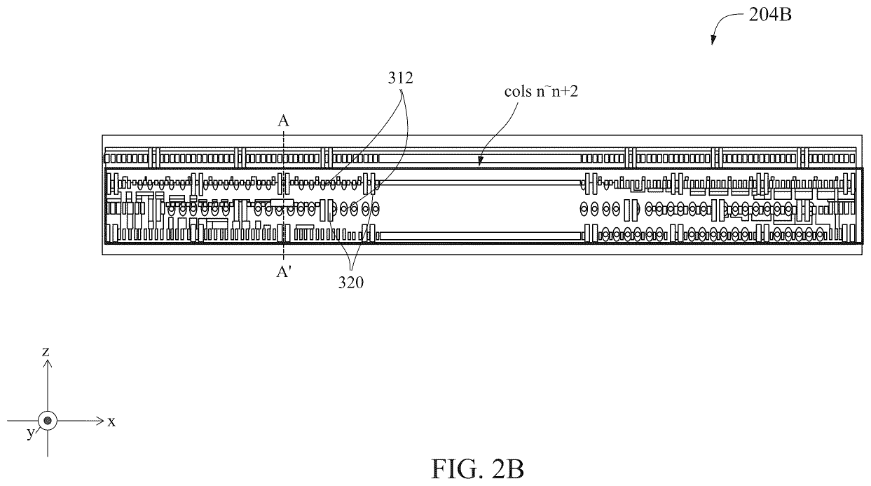

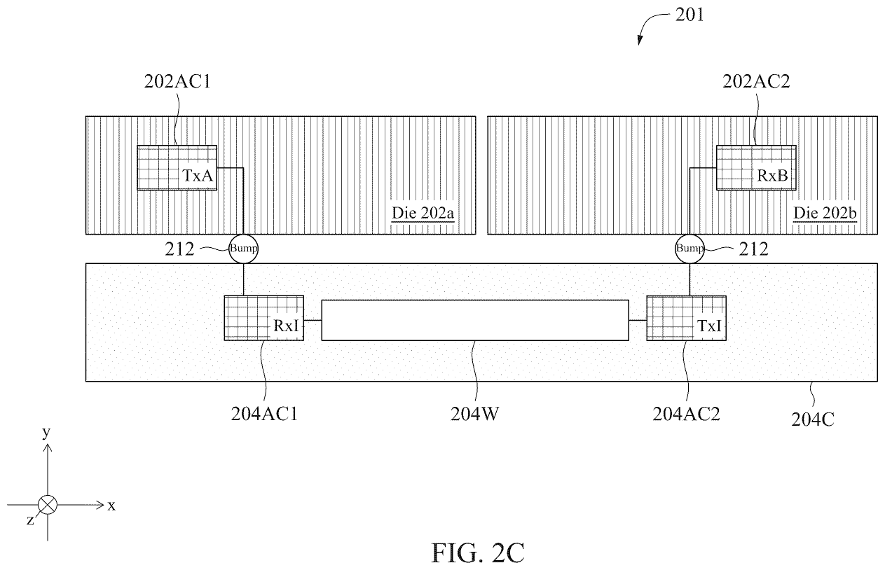

FIG. 2A is a schematic cross-section along a Y-Z plane of an interconnect 204A according to some embodiments.

In some embodiments, the interconnect 204A corresponds to the interconnect 104. Elements of interconnect 204A having a similar structure and function as elements of interconnect 104 in the description of FIG. 1 have a same identifying numeral, incremented by 100, unless stated otherwise or otherwise apparent.

In FIG. 2A, a substrate 210 is provided with a plurality of layers of conductive wiring, with a conductive layer Mz being disposed closest to a first surface S1 (the bump surface) of the substrate 210, a conductive layer Mz−1 being disposed under the conductive layer Mz, a conductive layer Mi being disposed under the conductive layer Mz−1, and a conductive layer Mi-1 being disposed under the conductive layer Mi. In some embodiments, the substrate 210 is a silicon substrate or the like.

In some embodiments, the conductive layer Mz is the conductive layer closest to the first surface S1 among all conductive layers (i.e., wiring layers) in the interconnect 204A (e.g., for a case in which the interconnect 204A includes seventeen conductive layers, the conductive layer Mz is the seventeenth conductive layer, although this is merely for the sake of explanation and embodiments can have any suitable number of conductive layers). In some embodiments, additional conductive layers are provided under the conductive layer Mi-1.

The conductive layers in the substrate 210 provide wiring such as signal wiring, power and ground wiring (e.g., a power delivery network), power planes, ground planes, and the like. In some embodiments, at least some of the conductive layers provide signal wiring that carries signals between first and second dies (not shown in FIG. 2A) that are mounted to the interconnect 204A.

First, second, and third conductive bumps 212a, 212b, and 212c (collectively or individually, referred to as conductive bump 212) are respectively arranged in a first column coln, a second column coln+1, and a third column coln+2 at the first surface S1. The first, second, and third columns coln, coln+1, and coln+2 are three columns of a set m of columns, where n is a positive integer and m is a positive integer of 3 or more, e.g., m=8, m=10, m=16, or the like. The columns are spaced apart in a third direction parallel to the Z axis, and the columns extend parallel to the X axis. In some embodiments, an edge of a die, e.g., the first die 102a or the second die 102b, extends parallel to the Z axis and the columns extend perpendicular to the die edge.

The conductive bumps 212 provide electrical connections between the interconnect 204A and a die (not shown in FIG. 2A) that is bonded at the first surface S1, e.g., one of the first or second dies 102a or 102b described above. In some embodiments, one or more of the conductive bumps 212 also provide a mechanical or bonding connection between the interconnect 204A and the die. In some embodiments, the conductive bumps 212 are arranged according to a bump map. In some embodiments, the bump map corresponds to, or is based on, a specification such as a Universal Chiplet Interconnect Express (UCIe) specification.

In FIG. 2A, the first conductive bump 212a and the third conductive bump 212c are in a same row, whereas the second conductive bump 212b is in a different row from the first and third conductive bumps 212a and 212c (hence, the second conductive bump 212b is shown with a dashed-line circle). In some embodiments, each row extends parallel to the Z-direction, e.g., parallel to a die edge. The first, second, and third conductive bumps 212a, 212b, and 212c are spaced in the Z-direction according to a regular pitch, denoted as column pitch 212CP in FIG. 2A.

In some embodiments, the column pitch 212CP is set with reference to a specification such as a UCIe specification. Merely by way of example, in a non-limiting embodiment, an example value for the column pitch 212CP is 38.88 um, although greater or smaller column pitches are used in various embodiments. In FIG. 2A, the first and third conductive bumps 212a and 212c, which are in a same row, are spaced at twice the column pitch 212CP. Merely by way of example, in a non-limiting embodiment, an example of the center-to-center distance of the first and third conductive bumps 212a and 212c along the row is 77.76 μm, although greater or smaller distances are used in various embodiments.

In some embodiments, the first, second, and third columns coln, coln+1, and coln+2 are three among ten columns included in a first connecting module that connects a first die to the interconnect 204A (e.g., the first die 102a described above), and which are in communication with a second ten-column connecting module that connects a second die (e.g., the second die 102b described above) to the interconnect 204A. It will be understood that ten columns is merely an example. In other embodiments, greater than or fewer than ten columns are used, e.g., eight columns or sixteen columns. Further, each die may be coupled to the interconnect 204A by a plurality of modules each including a plurality of columns of conductive bumps 212.

At least some of the conductive bumps 212 convey signals between a die and the interconnect 204A. At least a portion of the signals are routed through signal wiring in the conductive layers Mz and Mz−1 within the interconnect 204A. The conductive layers Mz and Mz−1 also include ground wiring, which is configured relative to the signal wiring in the conductive layers Mz and Mz−1 so as to enhance signal integrity and control for factors such as insertion loss, return loss, near-end crosstalk, and far-end crosstalk. The ground wiring is configured such that at least a portion thereof is continuous in a region of the interconnect 204A where the signal wiring is provided. In some embodiments, the continuous ground wiring structure of the interconnect 204A significantly reduces crosstalk while having equivalent insertion loss and return loss values as compared to another approach that does not use a continuous ground wiring structure.

In FIG. 2A, ground lines 214 include a first plurality of ground lines 214a in the conductive layer Mz and a second plurality of ground lines 214b in lower-adjacent conductive layer Mz−1. Further, signal lines 216 include a first plurality of signal lines 216a in the conductive layer Mz and a second plurality of signal lines 216b in lower-adjacent conductive layer Mz−1. In some embodiments, the conductive layers Mz and Mz−1 include an interconnect wiring structure in which the first plurality of ground lines 214a extend in a first direction (e.g., parallel to the X axis) in the conductive layer Mz, the first plurality of signal lines 216a extend in the first direction in the conductive layer Mz and alternate with the ground lines 214a along a third direction (e.g., parallel to the Z axis) in the conductive layer Mz, and the second plurality of ground lines 214b extend in the first direction in the conductive layer Mz−1 (e.g., below the first plurality of ground lines 214a and the first plurality of signal lines 216a relative to a second direction (parallel to the Y axis)), with at least a portion of the first plurality of ground lines 214a being coupled to at least a portion of the second plurality of ground lines 214b to form a continuous ground wiring structure.

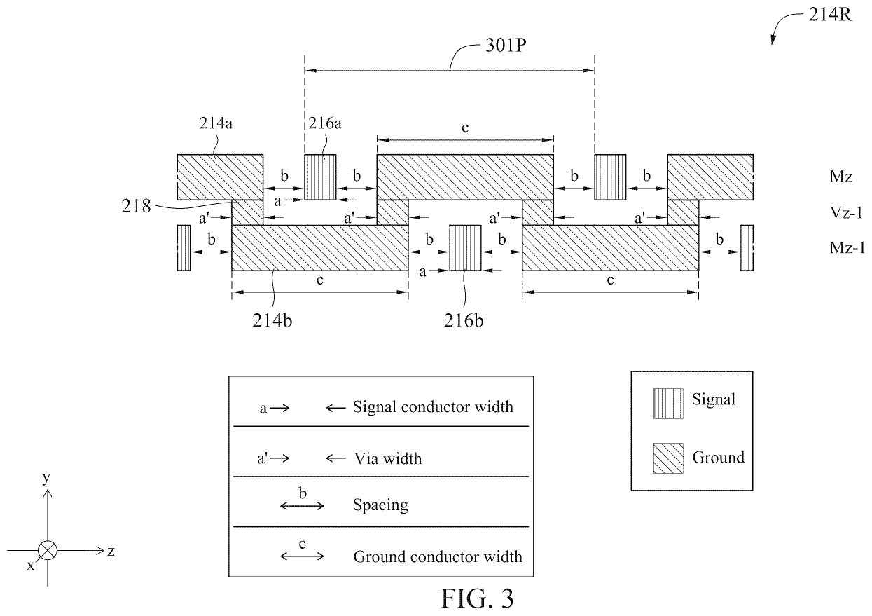

In FIG. 2A, by way of example, ground line 214a-1 through ground line 214b-n are included in a continuous ground wiring structure within the conductive layers Mz and Mz−1 (the continuous ground wiring structure within the conductive layers Mz and Mz−1 is considered to include via structures 218 in via layer Vz connecting the conductive layers Mz and Mz−1). That is, an unbroken ground wiring structure is present within the conductive layers Mz and Mz−1. A region 214R of continuous ground wiring structure in FIG. 2A is shown in greater detail in FIG. 3.

On the other hand, in FIG. 2A, merely by way of example, another ground line 214x is shown in conductive layer Mz. The ground line 214x is not coupled by a via in layer VZ to another ground line in the conductive layers Mz and Mz−1. Thus, the ground line 214x is not part of the continuous ground wiring structure within the conductive layers Mz and Mz−1.

In some embodiments, the signal lines 216 and the ground lines 214 are arranged within each of the conductive layers Mz and Mz−1 such that each signal line 216 is separated (in the Z-axis direction) from an immediately-adjacent signal line 216 within the same conductive layer Mz or Mz−1 by a ground line 214. For example, signal line 216a-1 is separated (in the Z-axis direction) from immediately-adjacent signal line 216a-2 within conductive layer Mz by ground line 214a-2. As another example, signal line 216b-1 is separated (in the Z-axis direction) from immediately-adjacent signal line 216b-2 within conductive layer Mz−1 by ground line 214b-2.

In some embodiments, at least one signal from a first die (e.g., the first die 102a described above) is coupled to the interconnect 204A by one or more of the conductive bumps 212, is carried through the interconnect 204A by one or more of the first plurality of signal lines 216a in the conductive layer Mz and/or one or more of the second plurality of signal lines 216b in the conductive layer Mz−1, and is coupled from the interconnect 204A to a second die (e.g., the second die 102b described above) by one or more corresponding conductive bumps 212. At least a portion of this signal path is bounded by a region of continuous ground wiring structure, e.g., the region 214R, in the conductive layers Mz and Mz−1. In some embodiments, all signal lines 216 in either of the conductive layers Mz and Mz−1 between a given conductive bump 212 and a conductive bump 212 in an immediately-adjacent column are bounded on both sides (relative to the Z-axis direction or bump-pitch direction) by ground lines of the continuous ground wiring structure within the corresponding conductive layer Mz or Mz−1.

In FIG. 2A, ones of the first plurality of ground lines 214a vertically overlap ones of the second plurality of ground lines 214b and are connected thereto by vertical via structures 218 in via layer Vz−1 that extend between the conductive layers Mz and Mz−1. A portion of a continuous ground wiring structure in the interconnect 204A thus includes a first ground line 214a-1 in the conductive layer Mz, a first via structure 218-1 in via layer Vz−1, a second ground line 214b-1 in the conductive layer Mz−1, a second via structure 218-2 in via layer Vz−1, and a third ground line 214a-2 in the conductive layer Mz. A first signal line 216a-1 in the conductive layer Mz is between the first and third ground lines 214a-1 and 214a-2 in the conductive layer Mz, and is over the second ground line 214b-1 in the conductive layer Mz−1.

In FIG. 2A, the ground lines 214 are coupled together continuously across all signal lines 216 that are located in the conductive layers Mz and Mz−1 between the first and third conductive bumps 212a and 212c, i.e., the ground lines 214 are coupled together continuously from a first side of the first signal line 216a-1 to a second side of an nth signal line 216b-n.

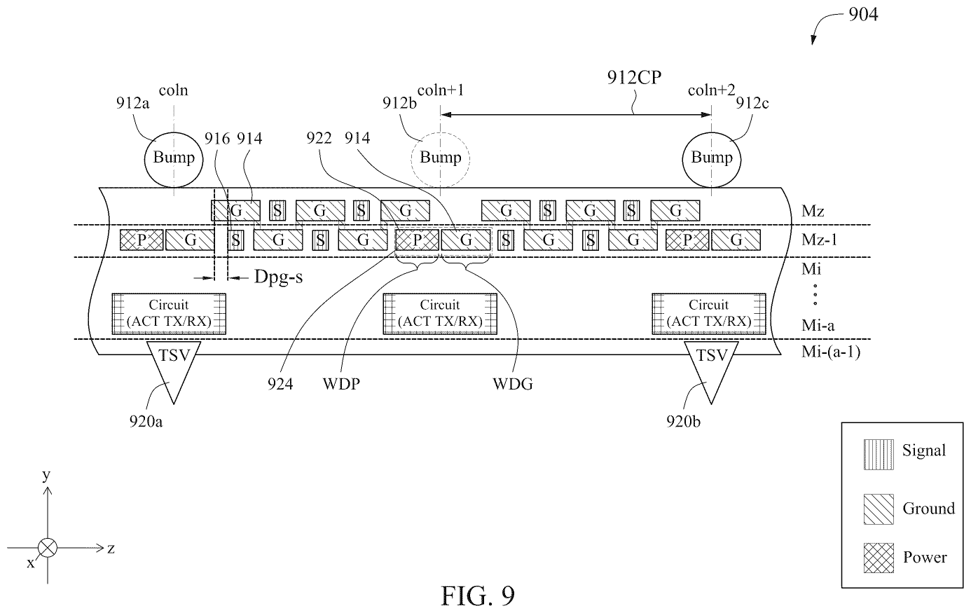

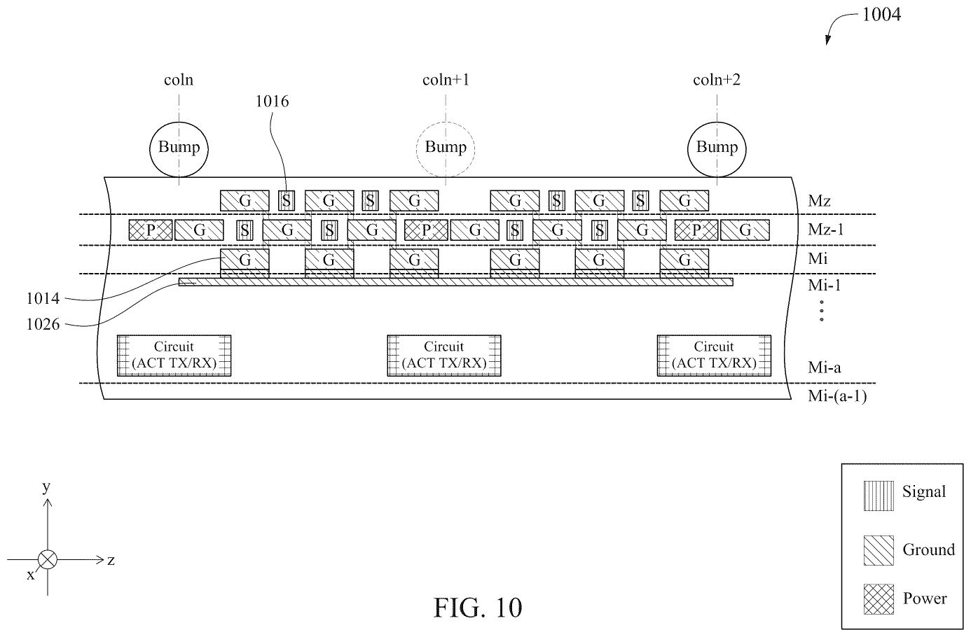

In other embodiments, the ground lines 214 are coupled together continuously across all signal lines 216 in the conductive layers Mz and Mz−1 between bumps in adjacent columns. Examples of such an arrangement are shown in FIGS. 9 and 10 described below.

In some embodiments, each signal line 216 of a plurality of signal lines 216 in the conductive layers Mz and Mz−1 and between conductive bumps 212 of adjacent columns (e.g., coln and coln+1, or coln+1 and coln+2) is disposed between a pair of ground lines 214 in the corresponding conductive layer Mz or Mz−1, and the pairs of ground lines 214 are continuously coupled (e.g., by the via structures 218) within the first and second conductive layers Mz and Mz−1 from a first side to a second side of the plurality of signal lines 216. An example of such an arrangement is shown in FIG. 2A.

In some embodiments, each signal line 216 in the conductive layers Mz and Mz−1 in a region between two adjacent bumps (e.g., in a region between the first conductive bump 212a and the second conductive bump 212b) is entirely vertically overlapped by a ground line 214 in one of the conductive layers Mz or Mz−1. An example of such an arrangement is shown in FIG. 2A. It will be understood that the term “vertically overlapped” means overlapped with respect to the Y-axis direction. A virtual vertical reference line RL1 in FIG. 2A intersects both the nth signal line 216b-n and an nth ground line 214a-n, and thus the signal line 216b-n is vertically overlapped by the nth ground line 214a-n. Further, an entire width WDS of the nth signal line 216b-n is vertically overlapped by the nth ground line 214a-n. Thus, the signal line 216b-n is entirely vertically overlapped by the nth ground line 214a-n.

In some embodiments, the interconnect 204A is a silicon interconnect or includes a local silicon interconnect in an organic substrate (e.g., FR4 or the like), and the conductive bumps 212 are arranged between, and coupling, a die and the silicon interconnect or local silicon interconnect. In some embodiments, the silicon interconnect or the local silicon interconnect includes through-silicon vias (TSVs). In FIG. 2A, a first TSV 220a is aligned with the first column coln of conductive bumps 212 and a second TSV 220b is aligned with the third column coln+2 of conductive bumps 212. The TSVs may be referred to individually or collectively as TSVs 220.

In some embodiments, the ground lines 214 are coupled together continuously across all signal lines 216 that are located in the conductive layers Mz and Mz−1 between adjacent TSVs 220 (e.g., between the first and second TSVs 220a and 220b). In some embodiments, each signal line 216 in the conductive layers Mz and Mz−1 in a region between adjacent TSVs 220 (e.g., between the first and second TSVs 220a and 220b) is entirely vertically overlapped by a ground line 214 in one of the conductive layers Mz or Mz−1.

The interconnect 204A further includes a first power/ground pair 224a that includes a power line 222a and a ground line 214c-1, and a second power/ground pair 224b that includes a power line 222b and a ground line 214c-2. The power/ground pairs may be referred to individually or collectively as power/ground pairs 224. In FIG. 2A, the first and second power/ground pairs 224a and 224b are both in the conductive layer Mz−1. In other embodiments, the power/ground pairs 224 are together in a different conductive layer. In still other embodiments, the power/ground pairs 224 are separated or distributed in a plurality of conductive layers. In FIG. 2A, the first power/ground pair 224a corresponds to the first column coln of the conductive bumps 212 and the second power/ground pair 224b corresponds to the third column coln+2 of the conductive bumps 212. In other embodiments, a power/ground pair 224 is provided to correspond to each column of conductive bumps 212 (examples of such an arrangement are shown in FIGS. 9 and 10). The power/ground pairs 224 can help to reduce IR drop in the interconnect 204A.

In FIG. 2A, the ground lines 214c-1 and 214c-2 of the first and second power/ground pairs 224a and 224b are electrically connected via conductive layer Mi to the continuous ground wiring structure that includes the first plurality of ground lines 214a and the second plurality of ground lines 214b. In other embodiments, electrical connections within the conductive layers Mz and Mz−1 are used instead of, or in addition to, the electrical connections in the conductive layer Mi to electrically connect the ground lines 214c-1 and 214c-2 to the continuous ground wiring structure.

In some embodiments, one or more of the power/ground pairs 224 is aligned with a corresponding TSV 220. By way of example, in FIG. 2A, the first power/ground pair 224a is aligned with the first TSV 220a and the second power/ground pair 224b is aligned with the second TSV 220b. In some embodiments, a power line or a ground line of the power/ground pair 224 is coupled to a TSV 220. Aligning one or more power/ground pairs 224 with a corresponding TSV 220 simplifies connections between the power/ground pairs 224 and the TSVs 220. In some embodiments, the TSVs are arranged in rows and/or columns in a region where the conductive bumps 212 are provided, and ones of the TSVs along the rows and/or along the columns are coupled alternately to ground or power.

FIG. 2B is a plan view in the X-Z plane of an interconnect 204B according to some embodiments.

In FIG. 2B, a line A-A′ extending parallel to the Z axis corresponds to line A-A′ of FIG. 2A. Elements of interconnect 204B having a similar structure and function as elements of interconnect 204A in the description of FIG. 2A have a same identifying numeral, incremented by 100, unless stated otherwise or otherwise apparent.

FIG. 2B shows columns of conductive bumps 312 extending parallel to the X axis, the columns being spaced apart from each other along the Z axis. FIG. 2B also shows TSVs 320 arranged to generally overlap the columns of conductive bumps 312.

FIG. 2C is a schematic cross-section along an X-Y plane of an integrated circuit (IC) device 201 according to some embodiments.

Elements of integrated circuit device 201 having a similar structure and function as elements of integrated circuit device 101 in the description of FIG. 1 have a same identifying numeral, incremented by 100, unless stated otherwise or otherwise apparent.

The integrated circuit device 201 includes a first die 202a and a second die 202b. The first and second dies 202a and 202b are spaced apart in the first direction parallel to the X axis. In some embodiments, the first and second dies 202a and 202b are each integrated circuit dies, e.g., semiconductor dies.

The first and second dies 202a and 202b are interconnected through an interconnect 204C. The first and second dies 202a and 202b are bonded to a surface of the interconnect 204C in at least a part of a region where the respective die overlaps the interconnect 204C. In FIG. 2C, the interconnect 204C is an active next-level substrate, (e.g., a local silicon interconnect (LSI) in an organic substrate, a monolithic silicon interposer, or the like) that includes first and second circuits 204AC1 and 204AC2, and a plurality of conductive layers in which wiring 204W is formed between the first and second circuits 204AC1 and 204AC2. In some embodiments, at least one of the first and second circuits 204AC1 and 204AC2 includes active circuits. In some embodiments, at least one of the first and second circuits 204AC1 and 204AC2 includes active and passive circuits. In some embodiments, at least one of the first and second circuits 204AC1 and 204AC2 includes only passive circuits. In some embodiments, the interconnect 204C is a passive next-level substrate and the first and second circuits 204AC1 and 204AC2 each include only passive circuits.

Electrical connections provided by a plurality of conductive bumps 212 between the first die 202a and the interconnect 204C couple power, ground, and signal connections between a third circuit 202AC1 in the first die 202a and the first circuit 204AC1 in the interconnect 204C. For clarity, FIG. 2C shows one conductive bump 212 between the first die 202a and the interconnect 204C and one conductive bump 212 between the second die 202b and the interconnect 204C, but it will be understood that in practice multiple conductive bumps 212 are between the first die 202a and the interconnect 204C and multiple conductive bumps 212 are between the second die 202b and the interconnect 204C.

In some embodiments, the third circuit 202AC1 is a transmitting circuit and the first circuit 204AC1 is a receiving circuit. In some embodiments, the third circuit 202AC1 and the first circuit 204AC1 are transceivers. Different and/or additional circuits are implemented in one or both of the third and first circuits 202AC1 and 204AC1 in other embodiments.

Electrical connections provided by a plurality of conductive bumps 212 between the second die 202b and the interconnect 204C couple power, ground, and signal connections between a fourth circuit 202AC2 in the second die 202b and the second circuit 204AC2 in the interconnect 204C. In some embodiments, the fourth circuit 202AC2 is a receiving circuit and the second circuit 204AC2 is a transmitting circuit. In some embodiments, the fourth circuit 202AC2 and the second circuit 204AC2 are transceivers. Different and/or additional circuits are implemented in one or both of the fourth and second circuits 202AC2 and 204AC2 in other embodiments.

In some embodiments, a channel distance in the interconnect 204C is about 3000 μm or less, e.g., from 1000 μm to 2000 μm, the channel distance representing the length of wiring and/or circuits between the first and second dies 202a and 202b in the interconnect 204C (including the first and second circuits 204AC1 and 204AC2 and the wiring 204W).

In some embodiments, the continuous ground wiring structure discussed above in connection with FIG. 2A is present in the interconnect 204C in conductive layers that are interposed between the conductive bumps 212 and the first and second circuits 204AC1 and 204AC2. For example, in some embodiments, the ground lines 214a-1 through 214b-n discussed above in connection with FIG. 2A are present in the interconnect 204C in conductive layers Mz and Mz−1, which are below the conductive bumps 212 and above the first and second circuits 204AC1 and 204AC2.

FIG. 3 is a detailed view of region 214R of a continuous ground wiring structure in FIG. 2A according to some embodiments.

Referring to FIG. 3, adjacent signal lines 216 of the first plurality of signal lines 216a in the conductive layer Mz are arranged at a pitch 301P in the Z-axis direction. The signal lines 216 have a uniform width a in the Z-axis direction. The via structures 218 have a uniform width a′ in the Z-axis direction. In some embodiments, the width a′ of the via structures 218 corresponds to the width of overlap between the ground lines 214 connected by the via structures 218, e.g., ground line 214a overlaps ground line 214b in the Z-axis direction by the width a′ of the via structure 218 in FIG. 3. In some embodiments, the width a′ of the via structures 218 in the Z-axis direction is equal to the width a of the signal lines 216 in the Z-axis direction. The signal lines 216 are spaced apart in the Z-axis direction from adjacent conductors in the corresponding conductive layer Mz or Mz−1 by a spacing b. In some embodiments, the spacing b is greater than the width a of the signal lines 216, e.g., about 25% greater. The ground lines 214 have a uniform width c in the Z-axis direction.

The pitch 301P includes two signal line widths a, two via widths a′, and four spacings b. Merely by way of example, in a non-limiting embodiment, the signal line width a is 0.36 μm, the via width a′ is 0.36 μm, the spacing b is 0.45 μm, and (2*0.36 μm)+(2*0.36 μm)+(4*0.45 μm)=3.24 μm for the value of the pitch 301P, although greater or smaller values of the various widths are used in various embodiments.

In some embodiments, depending on a manufacturing process, the pitch 301P is about 10% or less of the column pitch 212CP. In some embodiments, depending on the manufacturing process, a minimum value of the pitch 301P is about 8% of the column pitch 212CP.

In some embodiments, the combined widths of the signal lines 216 is about 20% or more of the pitch 301P. Because the ground lines 214 are connected in a continuous ground wiring structure throughout the pitch 301P, the combined widths of the signal lines 216 is also about 20% or more of the ground wiring width for each pitch 301P. In some embodiments, the combined widths of the signal lines 216 being about 20% or more of the ground wiring width for each pitch 301P can help insure integrity of signals transmitted using the signal lines 216 by providing a relatively large signal line width-to-ground line width ratio, while also providing relatively densely-packed signal lines 216.

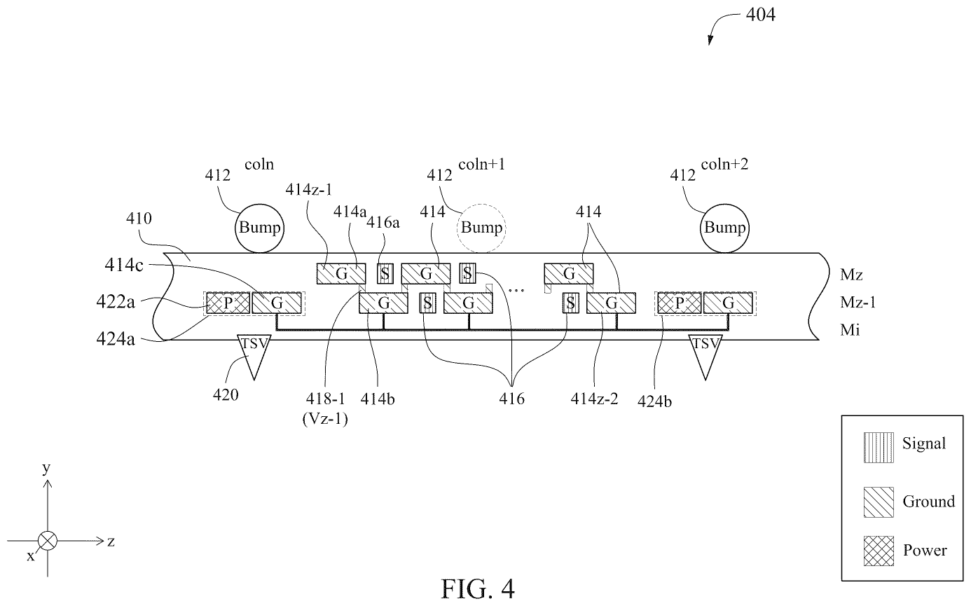

FIG. 4 is a schematic cross-section along a Y-Z plane of an interconnect 404 according to some embodiments.

Elements of interconnect 404 having a similar structure and function as elements of interconnect 204A in the description of FIG. 2A have a same identifying numeral, incremented by 200, unless stated otherwise or otherwise apparent.

Relative to the interconnect 204A described above, the interconnect 404 includes more signal lines 416 in the conductive layers Mz and Mz−1 in some embodiments, and includes fewer signal lines 416 in the conductive layers Mz and Mz−1 in other embodiments. In some embodiments, a number of signal lines 416 in each of the conductive layers Mz and Mz−1 is even, whereas in other embodiments a number of signal lines 416 in each of the conductive layers Mz and Mz−1 is odd, and in still other embodiments the number of signal lines 416 in one of the conductive layers Mz or Mz−1 is even whereas the number of signal lines 416 in the other of the conductive layers Mz or Mz−1 is odd.

In some embodiments, regardless of the number of signal lines 416 in the conductive layers Mz and Mz−1, the signal lines 416 are all disposed between a first bounding ground line 414z-1 at a first side of the signal lines 416 relative to the Z-axis direction and a second bounding ground line 414z-2 at a second side of the signal lines 416 relative to the Z-axis direction, with the first and second bounding ground lines 414z-1 and 414z-2 being coupled together within the conductive layers Mz and Mz−1 as part of a continuous ground wiring structure in the conductive layers Mz and Mz−1.

In some embodiments, regardless of the number of signal lines 416 in the conductive layers Mz and Mz−1, all signal lines 416 in either of the conductive layers Mz and Mz−1 between a bump 412 in a given column (e.g., in coln) and a bump 412 in an immediately-adjacent column (e.g., coln+1) are bounded on both sides (relative to the Z-axis direction or bump-pitch direction) by ground lines 414 of a continuous ground wiring structure within the corresponding conductive layer Mz or Mz−1.

Further, in some embodiments, regardless of the number of signal lines 416 in the conductive layers Mz and Mz−1, the signal lines 416 and the ground lines 414 are arranged within each of the conductive layers Mz and Mz−1 such that each signal line 416 is separated (in the Z-axis direction) from an immediately-adjacent signal line 416 within the same conductive layer Mz or Mz−1 by a ground line 414 of a continuous ground wiring structure within the corresponding conductive layer Mz or Mz−1.

Further, in some embodiments, regardless of the number of signal lines 416 in the conductive layers Mz and Mz−1, a region of continuous ground wiring structure is at least as wide in the Z-axis direction as a region that includes all of the signal lines 416, such that all of the signal lines 416 are vertically overlapped by the continuous ground wiring structure. In FIG. 4, by way of example, ground line 414z-1 through ground line 414z-2 are included in a continuous ground wiring structure within the conductive layers Mz and Mz−1. In some embodiments, the continuous ground wiring structure within the conductive layers Mz and Mz−1 is continuous across all signal lines 416 between a first bump in a given row and a second, immediately-adjacent bump in the given row. In some embodiments, the continuous ground wiring structure within the conductive layers Mz and Mz−1 is continuous across all signal lines 416 between a first column and a second, immediately-adjacent column. In some embodiments, the continuous ground wiring structure within the conductive layers Mz and Mz−1 is continuous across all signal lines 416 between a first TSV and a second, immediately-adjacent TSV. The continuous ground wiring structure can enhance signal integrity and control for factors such as insertion loss, return loss, near-end crosstalk, and far-end crosstalk. In some embodiments, the continuous ground wiring structure of the interconnect 404 significantly reduces crosstalk while having equivalent insertion loss and return loss values as compared to another approach that does not use a continuous ground wiring structure.

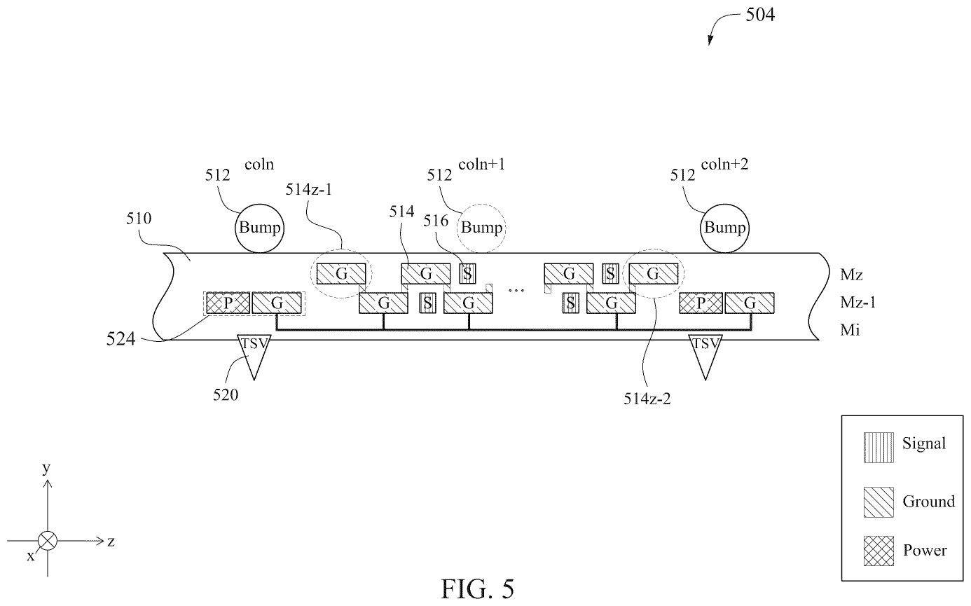

FIG. 5 is a schematic cross-section along a Y-Z plane of an interconnect 504 according to some embodiments.

Elements of interconnect 504 having a similar structure and function as elements of interconnect 204A in the description of FIG. 2A have a same identifying numeral, incremented by 300, unless stated otherwise or otherwise apparent.

In FIG. 5, the arrangement of signal lines varies relative to FIG. 4. Also, relative to the interconnect 204A described above, the interconnect 504 includes more signal lines 516 in the conductive layers Mz and Mz−1 in some embodiments, and includes fewer signal lines 516 in the conductive layers Mz and Mz−1 in other embodiments.

In some embodiments, regardless of the number of signal lines 516 in the conductive layers Mz and Mz−1, the signal lines 516 are all disposed between a first bounding ground line 514z-1 at a first side of the signal lines 516 relative to the Z-axis direction and a second bounding ground line 514z-2 at a second side of the signal lines 516 relative to the Z-axis direction, with the first and second bounding ground lines 514z-1 and 514z-2 being coupled together within the conductive layers Mz and Mz−1 as part of a continuous ground wiring structure in the conductive layers Mz and Mz−1.

Further, in some embodiments, regardless of the number of signal lines 516 in the conductive layers Mz and Mz−1, the number and/or arrangement of ground lines 514 can be varied. For example, in FIG. 5, a circled ground line 514z-1 in conductive layer Mz forms part of a continuous ground wiring structure even though there is no signal line in the conductive layer Mz adjacent to the ground line 514z-1, such that a continuous ground wiring structure is continued in a region of the conductive layers Mz and Mz−1 even though no signal line 516 is provided in the region. As another example, whereas bounding ground lines 414z-1 and 414z-2 of FIG. 4 are in respectively different conductive layers, bounding ground lines 514z-1 and 514z-2 of FIG. 5 are in the same conductive layer Mz. In still other embodiments, the bounding ground lines at ends of a continuous ground wiring structure are arranged such that the ground lines are both in conductive layer Mz−1 (not shown in FIG. 5).

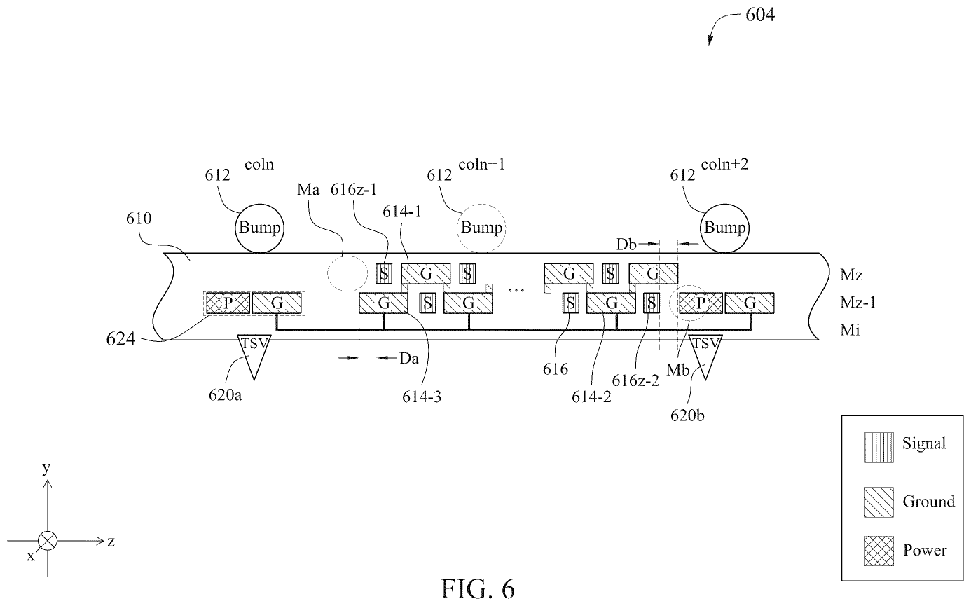

FIG. 6 is a schematic cross-section along a Y-Z plane of an interconnect 604 according to some embodiments.

Elements of interconnect 604 having a similar structure and function as elements of interconnect 204A in the description of FIG. 2A have a same identifying numeral, incremented by 400, unless stated otherwise or otherwise apparent.

In FIG. 6, the arrangement of signal lines is varied relative to FIG. 4. In FIG. 4 described above, the signal lines 416 are all disposed between a first bounding ground line 414z-1 at a first side of the signal lines 416 relative to the Z-axis direction and a second bounding ground line 414z-2 at a second side of the signal lines 416 relative to the Z-axis direction, with the first and second bounding ground lines 414z-1 and 414z-2 being coupled together within the conductive layers Mz and Mz−1 as part of a continuous ground wiring structure in the conductive layers Mz and Mz−1. In contrast, in FIG. 6, ground lines corresponding to the first and second bounding ground lines 414z-1 and 414z-2 are omitted.

That is, in FIG. 6, a signal line 616z-1 has a ground line 614-1 (which is part of a continuous ground wiring structure that is within the conductive layers Mz and Mz−1 and is continuous across all signal lines 616 that lie between a first TSV 620a and a second, immediately-adjacent TSV 620b) on one side thereof in conductive layer Mz, but the continuous ground wiring structure does not include another ground line at the other side of the signal line 616z-1 in a region Ma of the conductive layer Mz. Similarly, signal line 616z-2 includes a ground line 614-2 (which is part of the continuous ground wiring structure) on one side thereof in conductive layer Mz−1, but the continuous ground wiring structure does not include another ground line at the other side of the signal line 616z-2 in a region Mb of the conductive layer Mz−1. Nevertheless, the ground lines 614 of the continuous ground wiring structure extend laterally in the Z-axis direction beyond all signal lines 616 that lie between the first TSV 620a and the second, immediately-adjacent TSV 620b, as can be seen where ground line 614-3 extends laterally beyond signal line 616z-1 by a distance Da and where ground line 614-2 extends laterally beyond signal line 616z-2 by a distance Db.

In some embodiments, as in the example in FIG. 6, regardless of the number of signal lines 616 in the conductive layers Mz and Mz−1, the ground lines 614 of the continuous ground wiring structure extend laterally in the Z-axis direction beyond all signal lines 616 that lie between a bump 612 in a given column and a bump 612 in an immediately-adjacent column (e.g., coln and coln+1, or coln+1 and coln+2).

In some embodiments, as in the example in FIG. 6, regardless of the number of signal lines 616 in the conductive layers Mz and Mz−1, all signal lines 616 that lie between a bump 612 in a given column and a bump 612 in an immediately-adjacent column (e.g. coln and coln+1, or coln+1 and coln+2) have ground lines 614 (which are included in a continuous ground wiring structure) on both sides thereof in the corresponding conductive layer.

In some embodiments, as in the example in FIG. 6, regardless of the number of signal lines 616 in the conductive layers Mz and Mz−1, all signal lines 616 in either of the conductive layers Mz and Mz−1 between a bump 612 in a given column and a bump 612 in an immediately-adjacent column (e.g., coln and coln+1, or coln+1 and coln+2) are entirely vertically overlapped by a ground line 614 of the continuous ground wiring structure within the corresponding conductive layer Mz or Mz−1.

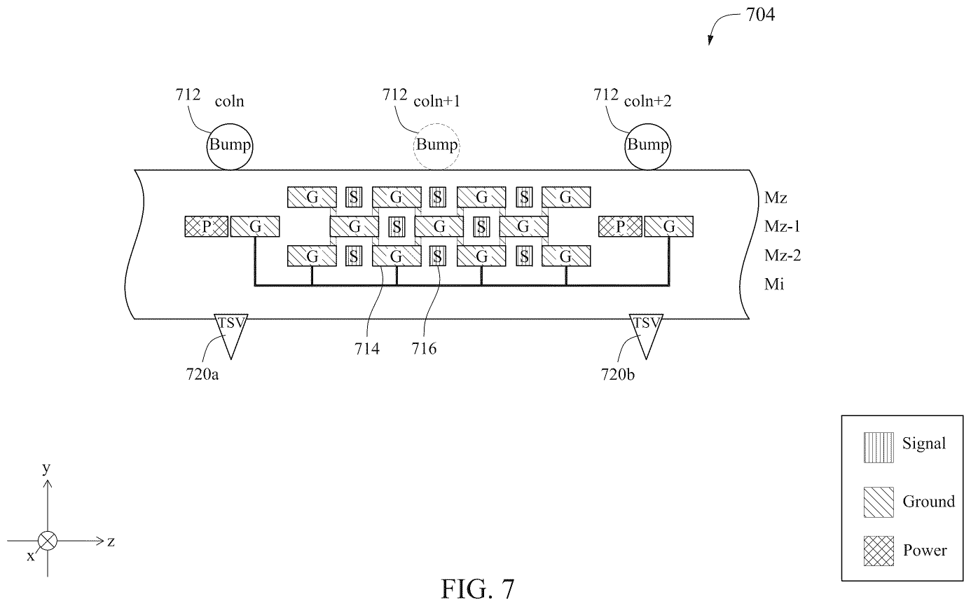

FIG. 7 is a schematic cross-section along a Y-Z plane of an interconnect 704 according to some embodiments.

Elements of interconnect 704 having a similar structure and function as elements of interconnect 204A in the description of FIG. 2A have a same identifying numeral, incremented by 500, unless stated otherwise or otherwise apparent.

In FIG. 7, the number of conductive layers used for the signal lines and the continuous ground wiring structure are varied, e.g., relative to FIG. 4. FIG. 7 illustrates an example in which the signal lines and ground lines/vias are arranged in three conductive layers Mz, Mz−1, and Mz−2. In other embodiments, more than three conductive layers are used. In some embodiments, the three conductive layers Mz, Mz−1, and Mz−2 are the three conductive layers closest to a bonding surface (bump surface) of the interconnect 704, from among all conductive layers (i.e., wiring layers) in the interconnect 704.

In some embodiments, as in the example in FIG. 7, regardless of the number of conductive layers used for signal lines 716, all of the signal lines 716 that lie between a first TSV 720a and a second, immediately-adjacent TSV 720b have ground lines 714 (which are included in a continuous ground wiring structure) on both sides thereof in the corresponding conductive layer.

In some embodiments, as in the example of FIG. 7, regardless of the number of conductive layers used for the signal lines 716, all signal lines 716 that lie between the first TSV 720a and the second, immediately-adjacent TSV 720b are entirely vertically overlapped by at least one ground line 714 (which is included in a continuous ground wiring structure) in the conductive layers.

In some embodiments, as in the example in FIG. 7, regardless of the number of conductive layers used for the signal lines 716, all signal lines 716 that lie between a bump 712 in a given column and a bump 712 in an immediately-adjacent column (e.g. coln and coln+1, or coln+1 and coln+2) have ground lines 714 (which are included in a continuous ground wiring structure) on both sides thereof in the corresponding conductive layer.

In some embodiments, as in the example in FIG. 7, regardless of the number of conductive layers used for the signal lines 716, all signal lines 716 in the conductive layers between a bump 712 in a given column and a bump 712 in an immediately-adjacent column (e.g., coln and coln+1, or coln+1 and coln+2) are entirely vertically overlapped by a ground line 714 (which is included in a continuous ground wiring structure) within one of the conductive layers.

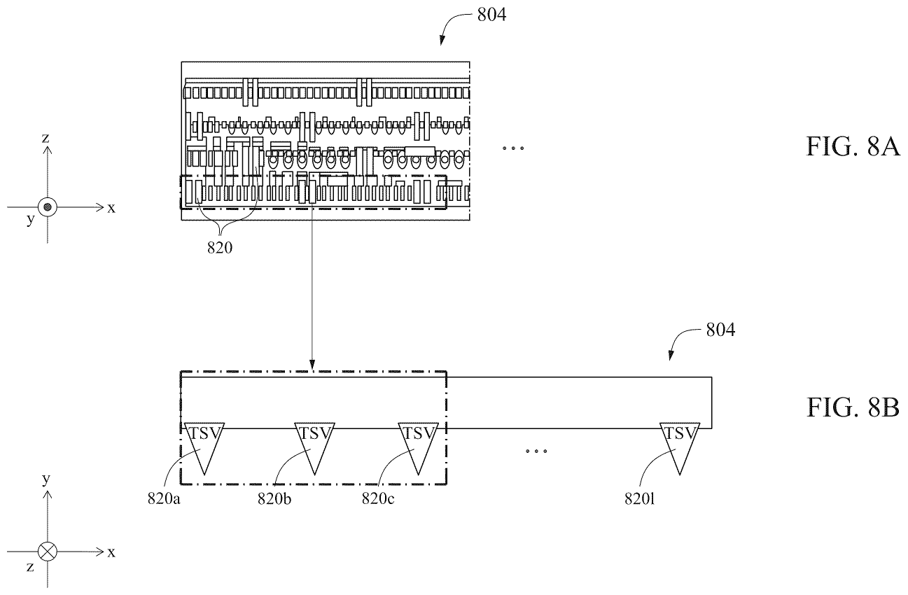

FIG. 8A is a plan view in the X-Z plane of an interconnect 804 according to some embodiments, and FIG. 8B is a schematic cross-sectional view of the interconnect 804 in the X-Y plane.

FIG. 8A is a partial, enlarged view of interconnect 204B.

Elements of interconnect 804 having a similar structure and function as elements of interconnect 204A in the description of FIG. 2A have a same identifying numeral, incremented by 600, unless stated otherwise or otherwise apparent.

Referring to FIGS. 8A and 8B, along the X-axis direction, in some embodiments TSVs 820a through 8201 (where ‘l’ is ‘last’) are arranged in sequence. That is, TSV 820a is directly adjacent to TSV 820b such that no other TSVs are interposed between TSV 820a and TSV 820b relative to the X-axis direction.

Referring to FIGS. 8A and 8B, along the X-axis direction, some TSVs are connected to power and some TSVs are connected to ground. In some embodiments, TSVs that are aligned along the X-axis direction are alternately connected to power and ground. For example, referring to FIG. 8B, in some embodiments, TSV 820a and TSV 820c are connected to power, and TSV 820B is connected to ground, with the alternating pattern continuing through any additional TSVs (e.g., fourth through 1-th TSVs) that are aligned along the X-axis direction.

FIG. 9 is a schematic cross-section along a Y-Z plane of an interconnect 904 according to some embodiments.

Elements of interconnect 904 having a similar structure and function as elements of interconnect 204A in the description of FIG. 2A have a same identifying numeral, incremented by 700, unless stated otherwise or otherwise apparent.

In FIG. 9, power/ground pairs 924 are provided for each column of conductive bumps 912 (which include conductive bumps 912a, 912b, and 921c in respective columns). In the power/ground pair 924, a power line 922 has a width WDP in the Z-axis direction (i.e., in the direction of column pitch 912CP), and a ground line 914 has a width WDG in the Z-axis direction. In some embodiments, the combined widths of the power and ground lines of the power/ground pair 924 (i.e., WDP+WDG) is about 15% or more of the column pitch 912CP. Merely by way of example, in a non-limiting embodiment, the column pitch 912CP is 38.88 μm, each of WDP and WDG is 3.1 μm, and ((2*3.1 μm)/38.88 μm)* 100=15.9%, although greater or smaller values of the various widths are used in various embodiments.

In some embodiments, a first TSV 920a and an immediately-adjacent, second TSV 920b are spaced apart at 2 times the column pitch 912CP. In some embodiments, the interconnect 904 includes thirty-two channels per cluster and two power/ground pairs 924 per cluster. In some embodiments, the width WDP is about the same as the width WDG. In some embodiments, the width WDG is about six to seven times that of a distance Dpg-s between the power/ground pair 924 and an immediately-adjacent signal line 616 in the same conductive layer, e.g., conductive layer Mz−1.

In FIG. 9, ground lines 914 of a first continuous ground wiring structure are coupled together continuously across all signal lines 916 in the conductive layers Mz and Mz−1 between bumps in adjacent columns coln and coln+1. Also, ground lines 914 of a second continuous ground wiring structure are coupled together continuously across all signal lines 916 in the conductive layers Mz and Mz−1 between bumps in adjacent columns coln+1 and coln+2.

FIG. 10 is a schematic cross-section along a Y-Z plane of an interconnect 1004 according to some embodiments.

Elements of interconnect 1004 having a similar structure and function as elements of interconnect 204A in the description of FIG. 2A have a same identifying numeral, incremented by 800, unless stated otherwise or otherwise apparent.

In the description of FIG. 2A above, it is noted that electrical connections in conductive layer Mi of FIG. 2A can be used to electrically connect the ground lines in overlying conductive layer Mz−1. An example structure for such electrical connections is shown in interconnect 1004 of FIG. 10, in conductive layer Mi−1.

Referring to FIGS. 2A and 10, the conductive layer Mi−1 (which corresponds to conductive layer Mi of FIG. 2A) includes a ground structure 1026 that electrically connects ground lines 1014 in overlying conductive layer Mi (which corresponds to conductive layer Mz−1 of FIG. 2A).

In FIG. 10, ground lines 1014 of a first continuous ground wiring structure are coupled together continuously across all signal lines 1016 in the conductive layers Mz and Mz−1 between bumps in adjacent columns coln and coln+1. Also, ground lines 1014 of a second continuous ground wiring structure are coupled together continuously across all signal lines 1016 in the conductive layers Mz and Mz−1 between bumps in adjacent columns coln+1 and coln+2.

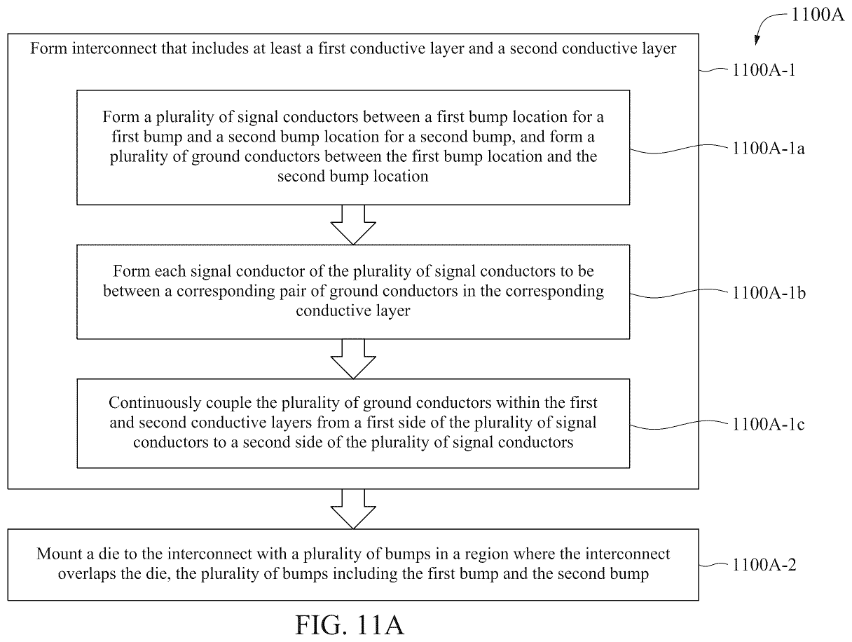

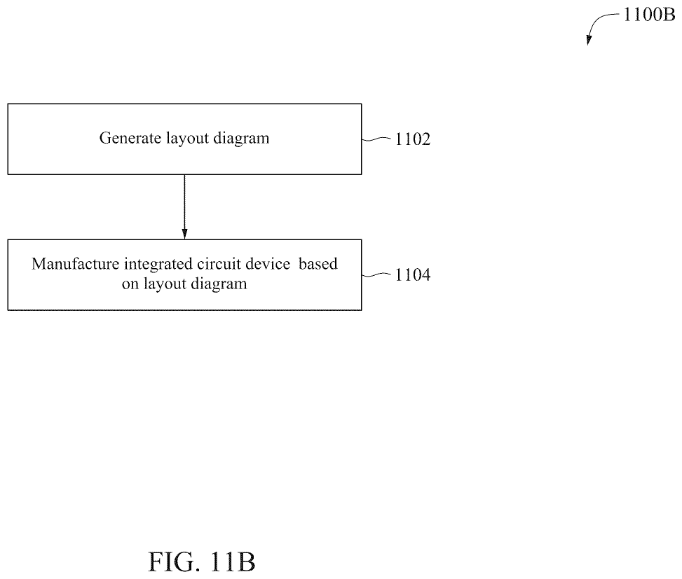

FIG. 11A is a flowchart of a method 1100A of manufacturing an integrated circuit device according to some embodiments.

In FIG. 11A, method 1100A includes blocks 1100A-1 and 1100A-2. Block 1100A-1 includes sub-blocks 1100A-1a, 1100A-1b, and 1100A-1c.

Block 1100A-1 includes forming an interconnect that includes at least a first conductive layer and a second conductive layer. Examples of the interconnect formed in block 1100A-1 include the interconnects 104, 204A, 204B, 204C, 404, 504, 604, 704, 804, and 904 described above, or the like.

In sub-block 1100A-1a, forming the first and second conductive layers of the interconnect includes forming a plurality of signal conductors between a first bump location for a first bump and a second bump location for a second bump, and forming a plurality of ground conductors between the first bump location and the second bump location.

In sub-block 1100A-1b, forming the plurality of signal conductors and the plurality of ground conductors includes forming each signal conductor of the plurality of signal conductors to be between a corresponding pair of ground conductors in the corresponding conductive layer.

In sub-block 1100A-1c, forming the plurality of ground conductors includes continuously coupling the plurality of ground conductors within the first and second conductive layers from a first side of the plurality of signal conductors to a second side of the plurality of signal conductors.

Block 1100A-2 includes mounting a die to the interconnect with a plurality of bumps in a region where the interconnect overlaps the die, the plurality of bumps including the first bump and the second bump.

FIG. 11B is a flowchart of a method 1100B of manufacturing an integrated circuit device according to some embodiments.

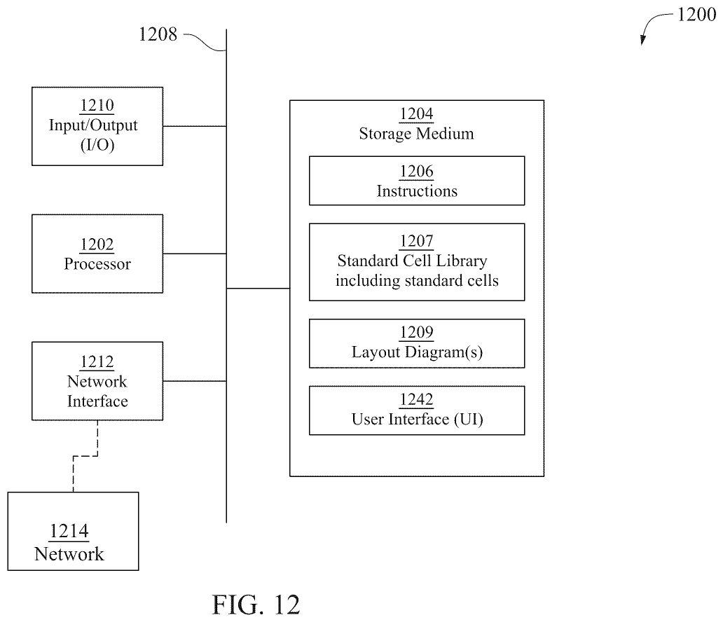

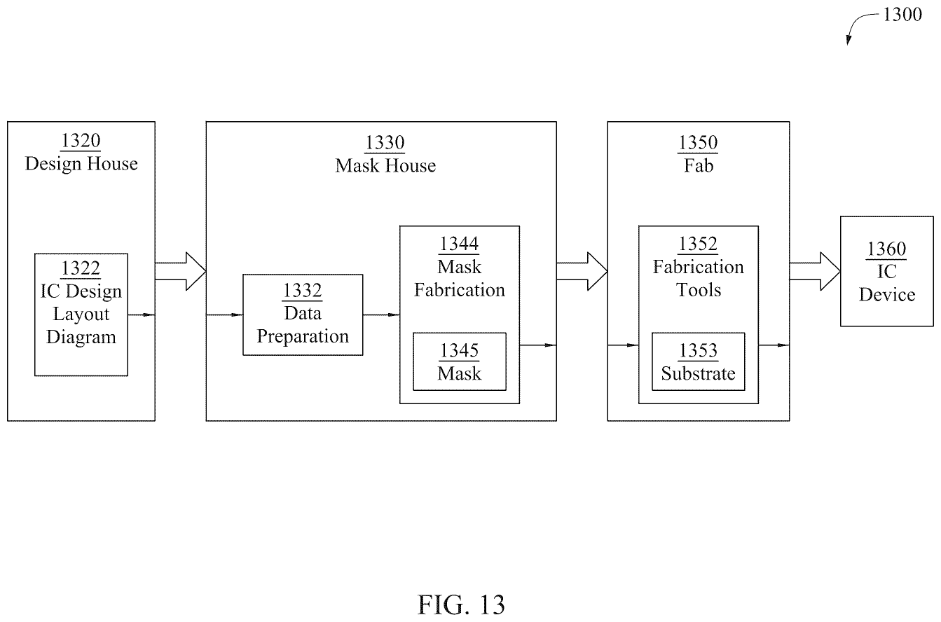

Method 1100B is implementable, for example, using EDA system 1200 (FIG. 12, discussed below) and an integrated circuit (IC) manufacturing system 1300 (FIG. 13, discussed below) according to some embodiments. Examples of an integrated circuit device that can be manufactured according to method 1100B include integrated circuit devices 101 and 201 described above, or the like.

In FIG. 11B, method 1100B includes blocks 1102 and 1104. At block 1102, a layout diagram is generated. Block 1102 is implementable, for example, using EDA system 1200 (FIG. 12, discussed below) according to some embodiments. In some embodiments, block 1102 includes generating shapes corresponding to structures in a semiconductor diagram which are to be represented.

At block 1104, based on the layout diagram, at least one of (A) one or more photolithographic exposures are made or (B) one or more semiconductor masks are fabricated or (C) one or more components in a layer of an integrated circuit (IC) device, e.g., a semiconductor device, are fabricated. See discussion below of FIG. 13.

FIG. 12 is a block diagram of an electronic design automation (EDA) system 1200 in accordance with some embodiments.

In some embodiments, EDA system 1200 includes an automatic placement and routing (APR) system. Methods described herein of designing layout diagrams represent wire routing arrangements, in accordance with one or more embodiments, are implementable, for example, using EDA system 1200 according to some embodiments.

In some embodiments, EDA system 1200 is a general purpose computing device including a hardware processor 1202 and a non-transitory, computer-readable storage medium 1204. Computer-readable storage medium 1204, amongst other things, is encoded with, i.e., stores, computer program code 1206, i.e., a set of executable instructions. Execution of instructions 1206 by processor 1202 represents (at least in part) an EDA tool which implements a portion or all of the methods described herein in accordance with one or more embodiments (hereinafter, the noted processes and/or methods).

Processor 1202 is electrically coupled to computer-readable storage medium 1204 via a bus 1208. Processor 1202 is also electrically coupled to an I/O interface 1210 by bus 1208. A network interface 1212 is also electrically connected to processor 1202 via bus 1208. Network interface 1212 is connected to a network 1214, so that processor 1202 and computer-readable storage medium 1204 are capable of connecting to external elements via network 1214. Processor 1202 is configured to execute computer program code 1206 encoded in computer-readable storage medium 1204 in order to cause EDA system 1200 to be usable for performing a portion or all of the noted processes and/or methods. In one or more embodiments, processor 1202 is a central processing unit (CPU), a multi-processor, a distributed processing system, an application specific integrated circuit (ASIC), and/or a suitable processing unit.

In one or more embodiments, computer-readable storage medium 1204 is an electronic, magnetic, optical, electromagnetic, infrared, and/or a semiconductor system (or apparatus or device). For example, computer-readable storage medium 1204 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1204 includes a compact disk-read only memory (CD-ROM), a compact disk-read/write (CD-R/W), and/or a digital video disc (DVD).

In one or more embodiments, computer-readable storage medium 1204 stores computer program code 1206 configured to cause EDA system 1200 (where such execution represents (at least in part) the EDA tool) to be usable for performing a portion or all of the noted processes and/or methods. In one or more embodiments, computer-readable storage medium 1204 also stores information which facilitates performing a portion or all of the noted processes and/or methods. In one or more embodiments, computer-readable storage medium 1204 stores library 1207 of standard cells including such standard cells as disclosed herein. In one or more embodiments, computer-readable storage medium 1204 stores one or more layout diagrams 1209 corresponding to one or more layouts disclosed herein.

EDA system 1200 includes I/O interface 1210. I/O interface 1210 is coupled to external circuitry. In one or more embodiments, I/O interface 1210 includes a keyboard, keypad, mouse, trackball, trackpad, touchscreen, and/or cursor direction keys for communicating information and commands to processor 1202.

EDA system 1200 also includes network interface 1212 coupled to processor 1202. Network interface 1212 allows EDA system 1200 to communicate with network 1214, to which one or more other computer systems are connected. Network interface 1212 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1200.

EDA system 1200 is configured to receive information through I/O interface 1210. The information received through I/O interface 1210 includes one or more of instructions, data, design rules, libraries of standard cells, and/or other parameters for processing by processor 1202. The information is transferred to processor 1202 via bus 1208. EDA system 1200 is configured to receive information related to a user interface (UI) through I/O interface 1210. The information is stored in computer-readable storage medium 1204 as UI 1242.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1200. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 13 is a block diagram of an integrated circuit (IC) manufacturing system 1300, and an IC manufacturing flow associated therewith according to some embodiments. In some embodiments, based on a layout diagram, at least one of (A) one or more semiconductor masks or (B) at least one component in a layer of a semiconductor integrated circuit is fabricated using IC manufacturing system 1300.

In FIG. 13, IC manufacturing system 1300 includes entities, such as a design house 1320, a mask house 1330, and an IC manufacturer/fabricator (fab) 1350, that interact with one another in the design, development, and manufacturing cycles and/or services related to manufacturing an IC device 1360. The entities in IC manufacturing system 1300 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1320, mask house 1330, and IC fab 1350 is owned by a single larger company. In some embodiments, two or more of design house 1320, mask house 1330, and IC fab 1350 coexist in a common facility and use common resources.

Design house (or design team) 1320 generates an IC design layout diagram 1322. IC design layout diagram 1322 includes various geometrical patterns designed for an IC device 1360. The geometrical patterns correspond to patterns of metal, oxide, or semiconductor layers that make up the various components of IC device 1360 to be fabricated. The various layers combine to form various IC features. For example, a portion of IC design layout diagram 1322 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1320 implements a proper design procedure to form IC design layout diagram 1322. The design procedure includes one or more of logic design, physical design or place and route. IC design layout diagram 1322 is presented in one or more data files having information of the geometrical patterns. For example, IC design layout diagram 1322 can be expressed in a GDSII file format or DFII file format.

Mask house 1330 includes mask data preparation 1332 and mask fabrication 1344. Mask house 1330 uses IC design layout diagram 1322 to manufacture one or more masks 1345 to be used for fabricating the various layers of IC device 1360 according to IC design layout diagram 1322. Mask house 1330 performs mask data preparation 1332, where IC design layout diagram 1322 is translated into a representative data file (RDF). Mask data preparation 1332 provides the RDF to mask fabrication 1344. Mask fabrication 1344 includes a mask writer. A mask writer converts the RDF to an image on a substrate, such as a mask (reticle) 1345 or a substrate 1353, e.g., a semiconductor wafer 1353. The IC design layout diagram 1322 is manipulated by mask data preparation 1332 to comply with particular characteristics of the mask writer and/or requirements of IC fab 1350. In FIG. 13, mask data preparation 1332 and mask fabrication 1344 are illustrated as separate elements. In some embodiments, mask data preparation 1332 and mask fabrication 1344 can be collectively referred to as mask data preparation.

In some embodiments, mask data preparation 1332 includes optical proximity correction (OPC) which uses lithography enhancement techniques to compensate for image errors, such as those that can arise from diffraction, interference, other process effects and the like. OPC adjusts IC design layout diagram 1322. In some embodiments, mask data preparation 1332 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1332 includes a mask rule checker (MRC) that checks the IC design layout diagram 1322 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1322 to compensate for photolithographic implementation effects during mask fabrication 1344, which may undo part of the modifications performed by OPC in order to meet mask creation rules.

In some embodiments, mask data preparation 1332 includes lithography process checking (LPC) that simulates processing that will be implemented by IC fab 1350 to fabricate IC device 1360. LPC simulates this processing based on IC design layout diagram 1322 to create a simulated manufactured device, such as IC device 1360. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1322.

It should be understood that the above description of mask data preparation 1332 has been simplified for the purpose of clarity. In some embodiments, mask data preparation 1332 includes additional features such as a logic operation (LOP) to modify the IC design layout diagram 1322 according to manufacturing rules. Additionally, the processes applied to IC design layout diagram 1322 during mask data preparation 1332 may be executed in a variety of different orders.

After mask data preparation 1332 and during mask fabrication 1344, a mask 1345 or a group of masks 1345 are fabricated based on the modified IC design layout diagram 1322. In some embodiments, mask fabrication 1344 includes performing one or more lithographic exposures based on IC design layout diagram 1322. In some embodiments, an electron-beam (e-beam) or a mechanism of multiple e-beams is used to form a pattern on a mask (photomask or reticle) 1345 based on the modified IC design layout diagram 1322. Mask 1345 can be formed in various technologies. In some embodiments, mask 1345 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1345 includes a transparent substrate (e.g., fused quartz) and an opaque material (e.g., chromium) coated in the opaque regions of the binary mask. In another example, mask 1345 is formed using a phase shift technology. In a phase shift mask (PSM) version of mask 1345, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1344 is used in a variety of processes. For example, such a mask(s) is used in an ion implantation process to form various doped regions in semiconductor wafer 1353, in an etching process to form various etching regions in semiconductor wafer 1353, and/or in other suitable processes.

IC fab 1350 is an IC fabrication business that includes one or more manufacturing facilities for the fabrication of a variety of different IC products. In some embodiments, IC fab 1350 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1350 includes fabrication tools 1352 configured to execute various manufacturing operations on semiconductor wafer 1353 such that IC device 1360 is fabricated in accordance with the mask(s), e.g., mask 1345. In various embodiments, fabrication tools 1352 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1350 uses mask(s) 1345 fabricated by mask house 1330 to fabricate IC device 1360. Thus, IC fab 1350 at least indirectly uses IC design layout diagram 1322 to fabricate IC device 1360. In some embodiments, semiconductor wafer 1353 is fabricated by IC fab 1350 using mask(s) 1345 to form IC device 1360. In some embodiments, the IC fabrication includes performing one or more lithographic exposures based at least indirectly on IC design layout diagram 1322. Semiconductor wafer 1353 includes a silicon substrate or other proper substrate having material layers formed thereon. Semiconductor wafer 1353 further includes one or more of various doped regions, dielectric features, multilevel interconnects, and the like (formed at subsequent manufacturing steps).

In some embodiments, an integrated circuit device includes: a die; an interconnect at least partially overlapping the die; and a plurality of bumps in a region where the interconnect overlaps the die. The interconnect includes at least a first conductive layer and a second conductive layer, the plurality of bumps includes a first bump and a second bump, which are spaced apart in a first direction, each of the first and second conductive layers includes a plurality of signal conductors between the first bump and the second bump and a plurality of ground conductors between the first bump and the second bump, and all of the signal conductors in each of the first and second conductive layers between the first bump and the second bump are between corresponding pairs of ground conductors in the corresponding conductive layer, and the pairs of ground conductors are continuously coupled within the first and second conductive layers from a first side of the plurality of signal conductors to a second side of the plurality of signal conductors.

In some embodiments, the first and second conductive layers include a first pair of power and ground conductors arranged side-by-side at the first bump and a second pair of power and ground conductors arranged side-by-side at the second bump. In some embodiments, the first bump and the second bump are spaced apart from each other by a bump pitch, and a combined width of the power and ground conductors of the first pair of power and ground conductors is about 10% or more of the bump pitch. In some embodiments, the combined width is about 15% or more of the bump pitch. In some embodiments, among the plurality of ground conductors, the ground conductors in the first conductive layer vertically overlap the ground conductors in the second conductive layer. In some embodiments, the integrated circuit device further comprises via structures between the ground conductors in the first and second conductive layers where the ground conductors in the first conductive layer vertically overlap the ground conductors in the second conductive layer. In some embodiments, each signal conductor in the first and second conductive layers in a region between the first bump and the second bump is entirely vertically overlapped in the first direction by a ground conductor in one of the first or second conductive layers. In some embodiments, the interconnect includes a first through-silicon via (TSV) and a second TSV, which are spaced apart in the first direction, and the first and second conductive layers include a first pair of power and ground conductors arranged side-by-side at the first TSV and a second pair of power and ground conductors arranged side-by-side at the second TSV. In some embodiments, all of the signal conductors in the first and second conductive layers between the first and second TSVs are between corresponding pairs of ground conductors in the corresponding conductive layer, and the pairs of ground conductors are continuously coupled within the first and second conductive layers from the first TSV to the second TSV. In some embodiments, the interconnect is bonded to the die and a second die, and at least some of the signal conductors are configured to couple signals between the die and the second die.

In some embodiments, an integrated circuit device includes: a die; an interconnect at least partially overlapping the die; and a plurality of bumps in a region where the interconnect overlaps the die. The interconnect includes at least a first conductive layer and a second conductive layer, the plurality of bumps includes at least a first bump and a second bump, which are spaced apart in a first direction, each of the first and second conductive layers includes signal and ground conductors in a region between the first bump and the second bump, and each signal conductor in each of the first and second conductive layers in the region between the first bump and the second bump is entirely vertically overlapped in the first direction by a ground conductor in one of the first or second conductive layers.

In some embodiments, the interconnect includes a first through-silicon via (TSV) and a second TSV, which are spaced apart in the first direction, and the first and second conductive layers include a first pair of power and ground conductors arranged side-by-side at the first TSV and a second pair of power and ground conductors arranged side-by-side at the second TSV. In some embodiments, signal conductors in the first and second conductive layers between the first and second TSVs are each between a pair of ground conductors in the corresponding conductive layer, and the pairs of ground conductors are continuously coupled from the first TSV to the second TSV. In some embodiments, the first bump and the second bump are spaced apart from each other by a bump pitch, and a combined width of the power and ground conductors of the first pair of power and ground conductors is about 10% or more of the bump pitch. In some embodiments, the combined width is about 15% or more of the bump pitch. In some embodiments, the first and second TSVs are spaced apart by about twice the bump pitch. In some embodiments, the interconnect includes a third TSV, the second TSV being between the first and third TSVs, the first and second conductive layers include a third pair of power and ground conductors arranged side-by-side at the third TSV, the first and third TSVs are coupled to one of the power or ground conductor of the corresponding first and third pairs of power and ground conductors, and the second TSV is coupled to the other of the power or ground conductor of the second pair of power and ground conductors. In some embodiments, the interconnect includes a first active circuit that vertically overlaps the first pair of power and ground conductors, and a second active circuit that vertically overlaps the second pair of power and ground conductors.

In some embodiments, a method of fabricating an integrated circuit device includes: forming an interconnect that includes at least a first conductive layer and a second conductive layer, wherein: forming the first and second conductive layers of the interconnect includes forming a plurality of signal conductors between a first bump location for a first bump and a second bump location for a second bump, and forming a plurality of ground conductors between the first bump location and the second bump location, forming the plurality of signal conductors and the plurality of ground conductors includes forming each signal conductor of the plurality of signal conductors to be between a corresponding pair of ground conductors in the corresponding conductive layer, and forming the plurality of ground conductors includes continuously coupling the plurality of ground conductors within each of the first and second conductive layers from a first side of the plurality of signal conductors to a second side of the plurality of signal conductors; and mounting a die to the interconnect with a plurality of bumps in a region where the interconnect overlaps the die, the plurality of bumps including the first bump and the second bump.

In some embodiments, forming the plurality of ground conductors includes: forming the ground conductors in the first conductive layer to vertically overlap the ground conductors in the second conductive layer, and forming via structures between the ground conductors in the first and second conductive layers where the ground conductors in the first conductive layer vertically overlap the ground conductors in the second conductive layer.

In some embodiments, a semiconductor device includes: a first die and a second die; and an interconnect structure below the first and second dies, wherein the interconnect structure includes: a plurality of first ground lines extending along a first direction; a plurality of first signal lines extending along the first direction, wherein the first ground lines and the first signal lines are arranged alternately along a second direction; and a plurality of second ground lines extending along the first direction below the first ground lines and the first signal lines, wherein the first and second ground lines are coupled together and arranged alternately along the second direction.

In some embodiments, a semiconductor device includes: a first die and a second die spaced apart along an X-axis direction; and an interconnect structure coupling signals and/or reference voltages between the first and second dies, wherein the interconnect structure includes: a plurality of first ground lines in a first conductive layer and spaced apart along the X-axis direction; a plurality of first signal lines in the first conductive layer in spaces between ones of the first ground lines such that the first grounds lines and signal lines alternate along the X-axis direction; and a plurality of second ground lines in a second conductive layer and spaced apart in the X-axis direction.

In some embodiments, the first and second ground lines are coupled together to form a continuous ground. In some embodiments, all of the first signal lines are between outermost ones of the ground lines that form the continuous ground. In some embodiments, a two-layer Mz, e.g., two uppermost metal layers, are used for signal routing.

In some embodiments, the first ground lines in a first conductive layer are closest to the first and second dies, from among the first and second ground lines, the first conductive layer is between the second conductive layer and the first and second dies, and the first conductive layer is spaced apart from the second conductive layer in the third direction. In some embodiments, the first ground lines vertically overlap the second ground lines, and the first ground lines are coupled to the second ground lines by vias.

In some embodiments, one or more through-silicon vias (TSV) are coupled to one or more of the ground lines and/or one or more of the signal lines, and extend from the signal lines in the third direction away from the first and second dies.

In some embodiments, a plurality of TSVs are alternatively arranged along the second direction.

In some embodiments, a conductive layer Mn that is directly under a two-layer Mz is thinner in the third direction than either of first or second conductive layers under the two-layer Mz.

As used herein, although terms such as “first,” “second” and “third” describe various elements, components, regions, layers and/or sections, these elements, components, regions, layers, and/or sections should not be limited by these terms. These terms may only be used to distinguish one element, component, region, layer, or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having skill in the art can understand that the acceptable standard error may vary according to different technologies. Other than in the operating/working examples, or unless otherwise expressly specified, all of the numerical ranges, amounts, values, and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless otherwise specified.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device comprising:
a die;
an interconnect at least partially overlapping the die; and
a plurality of bumps in a region where the interconnect overlaps the die, wherein:
the interconnect includes at least a first conductive layer and a second conductive layer,
the plurality of bumps includes a first bump and a second bump, which are spaced apart in a first direction,
each of the first and second conductive layers includes a plurality of signal conductors between the first bump and the second bump and a plurality of ground conductors between the first bump and the second bump, and
all of the signal conductors in each of the first and second conductive layers between the first bump and the second bump are between corresponding pairs of ground conductors in the corresponding conductive layer, and the pairs of ground conductors are continuously coupled within the first and second conductive layers from a first side of the plurality of signal conductors to a second side of the plurality of signal conductors.

2. The integrated circuit device of claim 1, wherein:
the first and second conductive layers include a first pair of power and ground conductors arranged side-by-side at the first bump and a second pair of power and ground conductors arranged side-by-side at the second bump.

3. The integrated circuit device of claim 2, wherein:
the first bump and the second bump are spaced apart from each other by a bump pitch, and
a combined width of the power and ground conductors of the first pair of power and ground conductors is about 10% or more of the bump pitch.

4. The integrated circuit device of claim 3, wherein:
the combined width is about 15% or more of the bump pitch.

5. The integrated circuit device of claim 1, wherein:
among the plurality of ground conductors, the ground conductors in the first conductive layer vertically overlap the ground conductors in the second conductive layer.

6. The integrated circuit device of claim 5, further comprising:
via structures between the ground conductors in the first and second conductive layers where the ground conductors in the first conductive layer vertically overlap the ground conductors in the second conductive layer.

7. The integrated circuit device of claim 5, wherein:
each signal conductor in the first and second conductive layers in a region between the first bump and the second bump is entirely vertically overlapped in the first direction by a ground conductor in one of the first or second conductive layers.

8. The integrated circuit device of claim 1, wherein:
the interconnect includes a first through-silicon via (TSV) and a second TSV, which are spaced apart in the first direction, and
the first and second conductive layers include a first pair of power and ground conductors arranged side-by-side at the first TSV and a second pair of power and ground conductors arranged side-by-side at the second TSV.

9. The integrated circuit device of claim 8, wherein:
all of the signal conductors in the first and second conductive layers between the first and second TSVs are between corresponding pairs of ground conductors in the corresponding conductive layer, and the pairs of ground conductors are continuously coupled within the first and second conductive layers from the first TSV to the second TSV.

10. The integrated circuit device of claim 1, wherein:
the interconnect is bonded to the die and a second die, and
at least some of the signal conductors are configured to couple signals between the die and the second die.

11. An integrated circuit device comprising:
a die;
an interconnect at least partially overlapping the die; and
a plurality of bumps in a region where the interconnect overlaps the die, wherein:
the interconnect includes at least a first conductive layer and a second conductive layer, the plurality of bumps includes at least a first bump and a second bump, which are spaced apart in a first direction,
each of the first and second conductive layers includes signal and ground conductors in a region between the first bump and the second bump, and
each signal conductor in each of the first and second conductive layers in the region between the first bump and the second bump is entirely vertically overlapped in the first direction by a ground conductor in one of the first or second conductive layers.

12. The integrated circuit device of claim 11, wherein:
the interconnect includes a first through-silicon via (TSV) and a second TSV, which are spaced apart in the first direction, and
the first and second conductive layers include a first pair of power and ground conductors arranged side-by-side at the first TSV and a second pair of power and ground conductors arranged side-by-side at the second TSV.

13. The integrated circuit device of claim 12, wherein:
signal conductors in the first and second conductive layers between the first and second TSVs are each between a pair of ground conductors in the corresponding conductive layer, and the pairs of ground conductors are continuously coupled from the first TSV to the second TSV.

14. The integrated circuit device of claim 12, wherein:
the first bump and the second bump are spaced apart from each other by a bump pitch, and
a combined width of the power and ground conductors of the first pair of power and ground conductors is about 10% or more of the bump pitch.

15. The integrated circuit device of claim 14, wherein:
the combined width is about 15% or more of the bump pitch.

16. The integrated circuit device of claim 14, wherein:
the first and second TSVs are spaced apart by about twice the bump pitch.

17. The integrated circuit device of claim 12, wherein:
the interconnect includes a third TSV, the second TSV being between the first and third TSVs,
the first and second conductive layers include a third pair of power and ground conductors arranged side-by-side at the third TSV,
the first and third TSVs are coupled to one of the power or ground conductor of the corresponding first and third pairs of power and ground conductors, and
the second TSV is coupled to the other of the power or ground conductor of the second pair of power and ground conductors.

18. The integrated circuit device of claim 12, wherein:
the interconnect includes a first active circuit that vertically overlaps the first pair of power and ground conductors, and a second active circuit that vertically overlaps the second pair of power and ground conductors.

19. A method of fabricating an integrated circuit device, the method comprising:
forming an interconnect that includes at least a first conductive layer and a second conductive layer, wherein:
forming the first and second conductive layers of the interconnect includes forming a plurality of signal conductors between a first bump location for a first bump and a second bump location for a second bump, and forming a plurality of ground conductors between the first bump location and the second bump location,
forming the plurality of signal conductors and the plurality of ground conductors includes forming each signal conductor of the plurality of signal conductors to be between a corresponding pair of ground conductors in the corresponding conductive layer, and
forming the plurality of ground conductors includes continuously coupling the plurality of ground conductors within each of the first and second conductive layers from a first side of the plurality of signal conductors to a second side of the plurality of signal conductors; and
mounting a die to the interconnect with a plurality of bumps in a region where the interconnect overlaps the die, the plurality of bumps including the first bump and the second bump.

20. The method of claim 19, wherein:
forming the plurality of ground conductors includes:
forming the ground conductors in the first conductive layer to vertically overlap the ground conductors in the second conductive layer, and
forming via structures between the ground conductors in the first and second conductive layers where the ground conductors in the first conductive layer vertically overlap the ground conductors in the second conductive layer.
